(19) United States
(12) Patent Application Publication
(10) Pub. No.: US 2001/0024462 A1
(43) Pub. Date: Sep. 27, 2001

(54) Semiconductor laser module

(76) Inventors: Kouji Nakahara, Kunitachi (JP); Kazuhisa Uomi, Hachiouji (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/739,692

(22) Filed: Dec. 20, 2000

(30) Foreign Application Priority Data
Sep. 21, 1999 (JP) 11-266669

(51) Int. Cl. H01S 5/00

(52) U.S. Cl. 372/43

(57) ABSTRACT

In order to realize a low-cost and small-sized optical transmitting module, which overcomes a bad influence of fluctuation in environment temperature on a FP laser for the optical communication, a heater 2 is sandwiched between the sub-mount 5 and the semiconductor laser 1 to increase temperature of the semiconductor 1 through the use of the heater 2. The temperature of the semiconductor laser 1 is sensed through the used of the temperature sensor 6, and the heater 2 is controlled through the use of the temperature control module 3 to keep the temperature of the semiconductor laser 1 higher than room temperature.

According to the present invention, since the temperature is kept constant at high temperatures, it is not affected by fluctuation in environment temperature, but fluctuation in the oscillation wavelength becomes small. Therefore, the transmission distance during high-speed modulation can be extended. Also, the transmitting module is small-sized, which leads to low cost and low power consumption.

### BACKGROUND OF THE INVENTION

The present invention relates to a light source using a semiconductor laser, and more particularly to stabilization of wavelength of emitted light from the semiconductor laser light source.

It is known that an oscillation wavelength from a light source using a semiconductor laser generally has temperature dependence (engineering book “Optical communication Element Optics” by Hiroo Yonetsu). Further it is also known that fluctuation in the oscillation wavelength affects a maximum transmission distance of a laser light source (IEEE Journal of Quantum Electronics, Vol. QE-18, No. 5, May 1982, pp.849-855). For example, in the case of a FP (Fabry-Perot) laser, which is one of typical semiconductor lasers to be used as a transmitting light source for optical communication, the oscillation wavelength of a semiconductor laser varies 0.45 nm/° C. at maximum due to changes in environment temperature (engineering book “Optical communication Element Optics” by Hiroo Yonetsu). For this reason, the oscillation wavelength varies 47 nm within a range from −20° C. to 85° C., which is an example of actual conditions of use.

Further, in addition to variations in oscillation wavelength accompanying variations in environment temperature, irregularity in oscillation wavelength caused by irregularity in the manufacture of the FP laser is conceivable, and since its range is currently about 15 nm, it must be considered that an oscillation wavelength fluctuation range of the FP laser actually reaches about 62 nm. In the case where the oscillation wavelength fluctuates within the fluctuation range of 62 nm as described above, the maximum transmission distance due to the FP laser remains at about 4 km as shown in FIG. 4, and cannot be used any longer as a light source for such long-distance optical transmission as to exceed 10 km (IEEE Journal of Quantum Electronics, Vol. QE-18, No. 5, May 1982, pp.849-855). For this reason, it is necessary to keep the temperature of the semiconductor laser constant for restraining the fluctuation in oscillation wavelength in order to make the maximum transmission distance longer.

Conventionally, as a method for stabilizing a wavelength from the semiconductor laser light source, there is a method of using a thermostat bath as disclosed in Japanese Patent Laid-Open Application No. 7-283475. In the literature, there has been disclosed an example in which a semiconductor laser and a temperature detector are provided within the same thermostat bath, and temperature in the thermostat bath is detected by a temperature detector to control temperature of the semiconductor laser on the basis of this detected temperature.

Also, as a conventional method for stabilizing the wavelength of the semiconductor laser light source, there is known a method for keeping the temperature constant by cooling a laser light source through the use of a Peltier cooling element as disclosed in Japanese Patent Laid-Open Application No. 7-302947. The Peltier cooling element has been used because it has been considered that a semiconductor laser element to be used for the semiconductor laser light source is vulnerable to heat, and when it is heated for many hours, its performance would be noticeably deteriorated. As disclosed in, for example, “Lasers and Their Applications” by M. J. Beesley, “The Laser” by W. V. Smith or “Gallium Arsenide Lasers” by C. H. Gooch, conventionally when an attempt is made to keep the temperature of the semiconductor laser constant in order to stabilize the wavelength, it has been necessary to keep the temperature of the semiconductor laser lower than the ambient air temperature through the use of such means as the Peltier cooling element.

An example in which the oscillation wavelength of the laser is controlled through the use of the Peltier element is disclosed in Japanese Patent Laid-Open Application No. 4-72783. In the official gazette, there has been disclosed an example in which a main surface (surface including an active layer) of the semiconductor laser element is provided with a heat source, a radiation block, whose temperature is controllable through the use of the Peltier element, is jointed to the rear surface (opposite surface to the main surface including the active layer), the temperature of the radiation block is controlled to become constant at about 20° C. by the Peltier element, and the refractive index of the active layer is caused to change by switching the temperature of the heat source for changing the oscillation wavelength in very short time. However, in the same literature, utilization of the heat source for keeping the wavelength constant has not been disclosed, but there has been described technique for disposing the heat source on the main surface side and not the rear surface side of the laser element, and combining it with the Peltier cooling element to control the wavelength in order to decisively change the oscillation wavelength rapidly.

On the other hand, in the case of further long-distance optical communication, which is difficult to transmit through the use of a FP laser, a DFB (distributed feedback) laser is used in many instances. Even in the case where this DFB laser is used as a light source, it has been reported that the optical transmission characteristic has temperature dependence (the 53rd Extended Abstracts of The Japan Society of Applied Physics p.932, Lecture No. 27p-ZA-12).

However, since the Peltier cooling element is expensive, the wavelength stabilizing method using it has had a problem that the cost would be generally high. Also, the wavelength stabilizing method using the Peltier cooling element has had a problem that the power consumption would be great. Further, since a semiconductor laser light source module accompanying the Peltier cooling element must be provided with a Peltier radiation board, there has been a problem that the volume of the module would be increased to make miniaturization of the laser light source module for optical communication difficult.

### SUMMARY OF THE INVENTION

An object of the present invention is to realize a semiconductor laser module having stable wavelength capable of being used as a light source for long-distance optical transmission at low cost and at low power consumption. Also, it is a further object of the present invention to miniaturize such a semiconductor laser module.

It is another object of the present invention to provide a low-cost, and small-sized transmitting module having a longer transmission distance than before in a transmitting module using a FP laser, which is a transmitting light source for optical communication.

It is another object of the present invention to provide a low-cost, and small-sized transmitting module having excellent transmission characteristic in a transmitting module using a DFB laser, which is a transmitting light source for optical communication.

It is another object of the present invention to provide a low-cost, small-sized and high-output optical recording module in which a long-distance radiation image of single peak is obtainable in a semiconductor laser module for optical information. Further, it is another object of the present invention to realize a transceiver comprising a semiconductor laser light source and a semiconductor optical receiver included, which has realized wavelength stabilization at small size, at low cost and at low power consumption.

It is another object of the present invention to realize a semiconductor optical receiver which has realized light-receiving sensitivity stabilization at small size, at low cost and at low power consumption.

The above described objects of the present invention is achieved by a semiconductor laser module, comprising a semiconductor laser for controlling wavelength of light to be emitted from the semiconductor laser, wherein the wavelength is controlled by a heating element accompanying no Peltier cooling. The semiconductor laser module is provided with a heating element or a heater so as to be able to keep the temperature of the semiconductor laser constant without the use of the Peltier cooling element, whereby the temperature of the semiconductor laser is controlled to become constant.

Also, the above described object of the present invention is achieved by a semiconductor laser module, comprising a semiconductor laser; a driving circuit for driving the semiconductor laser; a heating element for controlling temperature of the semiconductor laser; a temperature sensor for sensing temperature near or around the semiconductor laser and the heating element; and a temperature control unit for controlling the heating element on the basis of temperature information from the temperature sensor, wherein the temperature control unit controls the heating element without the use of the Peltier cooling means such that the semiconductor laser is kept at the same temperature as ambient air temperature or higher than that.

Also, the above described object of the present invention is achieved by a semiconductor laser module, comprising: a semiconductor laser; a driving circuit for driving the semiconductor laser; a heating element for controlling the temperature of the semiconductor laser without involving a Peltier cooling operation; a temperature sensor for sensing temperature near or around the semiconductor laser and the heating element; and a temperature control unit for controlling the heating element on the basis of temperature information from the temperature sensor, wherein the temperature control unit controls the heating element such that the semiconductor laser is kept at the same temperature as ambient air temperature or higher than it.

Also, the above described object of the present invention is achieved by a semiconductor laser module, comprising: a semiconductor laser; a driving circuit for driving the semiconductor laser; a heating element for controlling the temperature of the semiconductor laser; a temperature sensor for sensing temperature near or around the semiconductor laser and the heating element; a temperature control unit for controlling the heating element on the basis of temperature information from the temperature sensor; and a supporting substrate, wherein at least the semiconductor laser, the heating element and the temperature sensor are mounted on a main surface of the supporting substrate, a main surface of a semiconductor chip of the semiconductor laser, on which joining for emitting laser light has been formed, is disposed on the main surface of the supporting substrate, the heating element is disposed in proximity to the joining on the main surface of the semiconductor chip of the semiconductor laser on the main surface of the supporting substrate, the temperature control unit controls the heating element so as to keep the semiconductor laser at the same temperature as ambient air temperature or higher than it.

Also, the above described object according to the present invention is achieved by an optical transceiver comprising an optical receiving module and an optical transmitting module, wherein the optical transmitting module comprises: a semiconductor laser; a driving circuit for driving the semiconductor laser; a heating element for controlling the temperature of the semiconductor laser without involving a Peltier cooling operation; a temperature sensor for sensing temperature near or around the semiconductor laser and the heating element; and a temperature control unit for controlling the heating element on the basis of temperature information from the temperature sensor, wherein the temperature control unit controls the heating element so as to keep the semiconductor laser at the same temperature as ambient air temperature or higher than it, and wherein the optical transmitting module and the optical receiving module are housed within one housing.

Also, the above described object of the present invention is achieved by an optical receiver, comprising: a semiconductor photo detector for receiving an optical information signal from a recording medium or a communication system; a signal processing unit for processing an electric signal from the semiconductor photo detector; a heating element for controlling temperature of the semiconductor photo detector; a temperature sensor for sensing temperature near or around the semiconductor photo detector and the heating element; a temperature control unit for controlling the heating element on the basis of the temperature information from the temperature sensor, wherein the temperature control unit controls the heating element without the use of the Peltier cooling means so as to keep the semiconductor photo detector at the same temperature as the ambient air temperature or higher than it.

### BRIEF DESCRIPTION OF THE DRAWINGS

FIG. 1 is a view showing structure of a first embodiment according to the present invention;

FIG. 2 is a view showing structure of the first embodiment according to the present invention;

FIG. 3 is a view showing an effect of the present invention;

FIG. 4 is a view showing an effect of the present invention;

FIG. 5 is a view showing structure of a second embodiment according to the present invention;

FIG. 6 is a view showing structure of a third embodiment according to the present invention;

FIG. 7 is a view showing structure of the third embodiment according to the present invention;

FIG. 8 is a view showing structure of a fourth embodiment according to the present invention; and

FIG. 9 is a view showing structure of a fifth embodiment according to the present invention.

### DETAILED DESCRIPTION OF THE PREFERRED EMBODIMENTS

(First Embodiment)

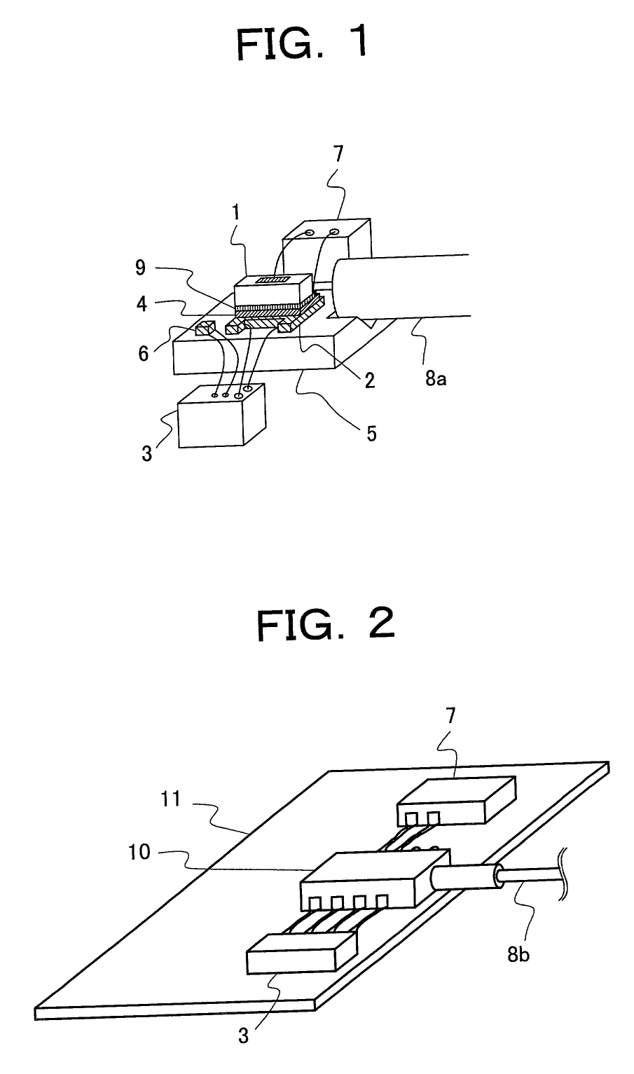

FIG. 1 shows an embodiment in which a semiconductor laser module according to the present invention has been applied to a transmitter for optical communication. In FIG. 1, a reference numeral 1 denotes a 1.3 μm band FP type semiconductor laser; 2, a Pt thin film heater (heating element); 3, a temperature control module; 4, insulating thin film made of SiO₂ for electrically separating the heater from the semiconductor laser and thermally combining them; 9, Ti, Pt, Au laminated thin film for joining the semiconductor laser to the SiO₂ thin film and solder of AuSn alloy on top thereof; 5, a Si sub-mount, in which there is partially provided a V-groove for fixing optical fiber 8a, and the top of which is covered with SiO₂ thin film; 7, a driving circuit for driving the semiconductor laser, connected to the upper electrode of the semiconductor laser and the solder 9; and 6, a temperature sensor placed near the semiconductor laser on the Si sub-mount. In order to obtain optical combination with optical fiber without oscillating the semiconductor laser, there are markers on the Si sub-mount and the semiconductor laser, and further, the semiconductor laser is provided in so-called junction-down, that is, with a surface close to the active layer as the lower surface.

A transmitter for optical communication according to the present embodiment may be constructed by molding each element on the Si sub-mount into a small-sized plastic module 10 as shown in, for example, FIG. 2, and connecting to the temperature control module 3 and the driving circuit 7 on the printed board 11. In FIG. 2, a reference numeral 8b denotes optical fiber coated.

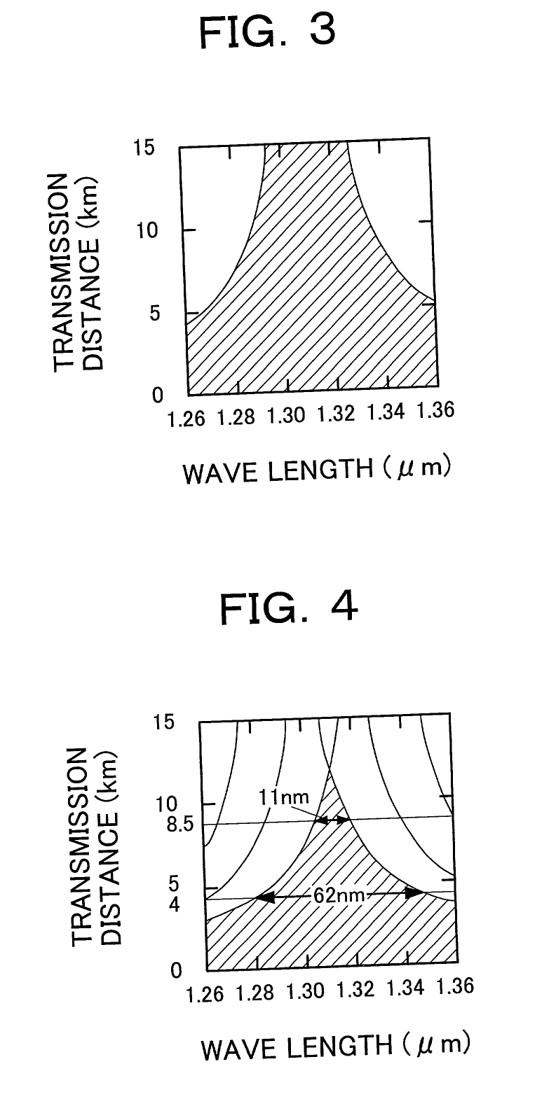

In the present embodiment, the temperature control module 3 is set so as to control at 84° C.±1° C. which is close to the highest value of environment temperature, higher than room temperature at all times by heating the heater 2, while sensing temperature of the semiconductor laser 1 through the use of the temperature sensor 6. For this reason, even though temperature fluctuates to 0 to 85° C., which is use environment temperature, temperature fluctuation of this FP type semiconductor laser itself becomes as low as 2° C., and as a result, fluctuation in oscillation wavelength of the FP type semiconductor laser due to temperature fluctuation is as exceedingly small as 1.1 nm. Even though variations 15 nm in oscillation wavelength due to the manufacture of the FP type semiconductor laser is included, the variations becomes 16.1 nm, and the transmission distance during 2.5 Gb/s driving can be enlarged to 8 km, about twice the conventional one as shown in FIG. 3.

In the present embodiment, in order to control temperature through the use of the heater 2, the size of the small-sized plastic module can be made into 0.25 cc, the same size as the transmitting module without Peltier. In contrast, the size of a transmitting module with Peltier becomes 2.5 cc, about ten times because a Peltier element and a radiation board for dissipating heat generated from the Peltier element are required. Also, in order to effectively give heat from the heater to the semiconductor laser and to minimize the power consumption of the heater, the size and thickness of the Si sub-mount and the thickness of SiO₂ insulating film which covers the sub-mount are changed, whereby heat resistance of the Si sub-mount as viewed from the semiconductor laser is set to as a middle level heat resistance as 50° C./W. Thereby, the power consumption of the heater can be reduced to 0.75 W at maximum, which is one half to one third of that of the transmitting module with Peltier. In the present embodiment, the transmitter of FIG. 2 is capable of obtaining transmission distance of 8 km or more at environment temperatures of 0 to 85° C. even though the FP type semiconductor laser is used as a transmitting light source. Further, the cost of the transmitting module with Peltier is further high in terms of the entire module because the part cost of the Peltier element is very high, whereas the transmitter for optical communication according to the present embodiment can be manufactured at as low a cost as about half the transmitting module with Peltier because the temperature control module can be manufactured at low cost and no high-cost parts are needed in addition.

Also, according to the present invention, since the temperature of the semiconductor laser increases, reliability of the semiconductor laser is feared, but since the reliability of the semiconductor laser has noticeably advanced in recent years and a semiconductor laser having reliability at 85° C. for 500,000 hours or more has been used in the present embodiment, there has no problem on reliability.

In this respect, the temperature control module has been set to 84° C.±2° C. in the present embodiment, but the present invention is not limited thereto, but the setting temperature may be arbitrarily set within a range of, for example, 60 to 85° C. with respect to an environment temperature range of 0 to 85° C. Since fluctuation in oscillation wavelength due to variations in temperature is 13.8 nm in this case, the transmission distance is reduced to 6.8 km, but the effect of the present invention that the wavelength of the semiconductor laser module is stabilized at low cost and at low power consumption can be maintained. In this respect, in this case, the temperature fluctuates and the threshold current of the semiconductor laser changes, and therefore, the temperature control module and the driving current may be connected to each other to transmit temperature information whereby the driving circuit is fabricated so as to change driving condition such as bias current in response to temperature.

Also, in the present embodiment, for the semiconductor laser, an ordinary one has been used, but the present invention is not limited thereto, and there may be used a semiconductor laser obtained by integrating a mode expander aimed at improving optical combination efficiency with optical fiber. Further, in the present embodiment, an optical fiber has been used, but the present invention is not limited thereto, but for example, a lens, or an optical wave guide may be provided on the Si sub-mount in place of the optical fiber in accordance with the transmitter. Also, as a temperature control method using a temperature control module, any well-known method can be used, and for example, PID control, digital control or the like may be used.

(Second Embodiment)

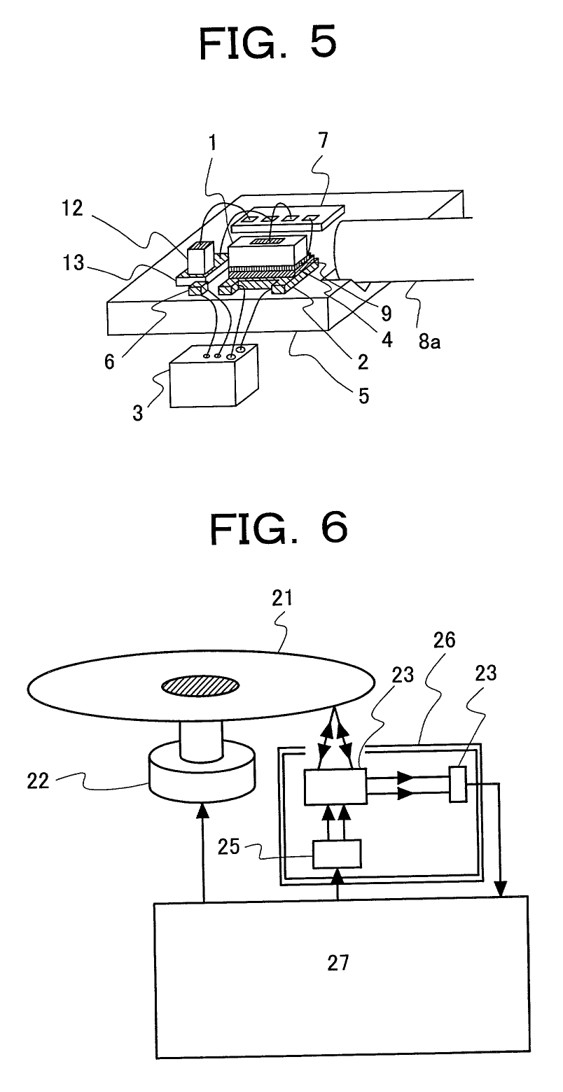

FIG. 5 shows another embodiment in which a semiconductor laser module according to the present invention has been applied to a transmitter for optical communication. In FIG. 5, a reference numeral 1 denotes a 1.3 μm band DFB type semiconductor laser; 2, a Pt thin film heater (heating element); 3, a temperature control module; 4, SiO₂ thin film for electrically separating the heater from the semiconductor laser and thermally combining them; 9, Ti, Pt, Au laminated thin film for joining the semiconductor laser to the SiO₂ thin film and solder of AuSn alloy on top thereof; 5, a Si sub-mount, in which there is partially provided a V-groove for fixing optical fiber 8, and the top of which is covered with SiO₂ thin film; 7, a driving IC circuit for driving the semiconductor laser provided on top of the Si sub-mount, connected to the upper electrode of the semiconductor laser and the solder 9; 12, an optical photo detector for optical output monitor of the semiconductor laser; 13, insulator thin film, SiO₂ and the optical photo detector is connected to the driving IC circuit, and is controlled so as to make optical output from the semiconductor laser constant. A reference numeral 6 denotes a temperature sensor placed near the semiconductor laser on the Si sub-mount. In order to obtain optical combination without oscillating the semiconductor laser, there are markers on the Si sub-mount and the semiconductor laser, and further, the semiconductor laser is provided in so-called junction-down, that is, with a surface close to the active layer as the lower surface.

The temperature control module 3 is set so as to control at 84° C.±1° C. which is close to the highest value of environment temperature, higher than room temperature at all times by heating the heater 2, while sensing temperature of the semiconductor laser 1 through the use of the temperature sensor 6. In the present embodiment, the use environment temperature range is −40 to 85° C., and conventionally, temperature fluctuation changes a detuned degree, and particularly in an element, whose detuned degree at room temperature is 0 to +10 nm, the characteristic during 2.5 Gb/s, 50 km transmission was deteriorated at low temperatures. In the present embodiment, however, since the temperature of the DFB type semiconductor laser is substantially constant even though the environment temperature changes, even in semiconductor lasers, whose detuned degree is 0 to +10 nm, the transmission characteristic during 2.5 Gb/s, 50 km transmission is not deteriorated. Therefore, a degree of design allowance of the DFB type semiconductor laser to the detuned degree becomes wider, the yield is improved, and the cost can be reduced.

In this respect, even in the present embodiment, each element on the Si sub-mount can be made into a small-sized plastic module by molding as in the first embodiment. Thus, it can be miniaturized as compared with the transmitting module with Peltier.

In this respect, in the present embodiment, the temperature of the temperature control module has been set to 84° C±2° C., but the present invention is not limited thereto, and the setting temperature may be arbitrarily set within a range of, for example, 60 to 85° C. with respect to an environment temperature range of 0 to 85° C. Also, in the present embodiment, for the semiconductor laser, an ordinary DFB type laser has been used, but the present invention is not limited thereto, and there may be used a DFB type semiconductor laser obtained by integrating a mode expander aimed at improving optical combination efficiency with optical fiber. Further, in the present embodiment, optical fiber has been used, and the present invention is not limited thereto, but for example, a lens, or an optical wave guide may be provided on the Si sub-mount in place of the optical fiber in accordance with the transmitter. Also, as a temperature control method using a temperature control module, any well-known method can be used, for example, PID control, digital control or the like may be used.

In the present embodiment, the DFB type semiconductor laser has been used, but the present invention is not limited thereto, it goes without saying that the same effect can be obtained even though a plane light-emitting type semiconductor laser is used.

In the present embodiment, the driving IC circuit has been connected onto the Si sub-mount, but the present invention is not limited thereto, the driving IC circuit may be monolithic-integrated with the Si sub-mount. As regards the temperature control module, it may be similarly provided on the Si sub-mount and may be monolithic-integrated. Further, as regards the temperature sensor and the heater, it goes without saying that the similar effect can be obtained even though either of them is monolithic-integrated.

(Third Embodiment)

FIG. 6 shows an embodiment in which a semiconductor laser module according to the present invention has been applied to an optical regenerated record device. In FIG. 6, a reference numeral 21 denotes an optical disk for the record; 22, a motor; 23, a lens system for handling spectrum, light concentration and the like; 24, a photodetector; 25, a light source unit having a semiconductor laser as a light source; 26, an optical pickup; and 27, a control circuit.

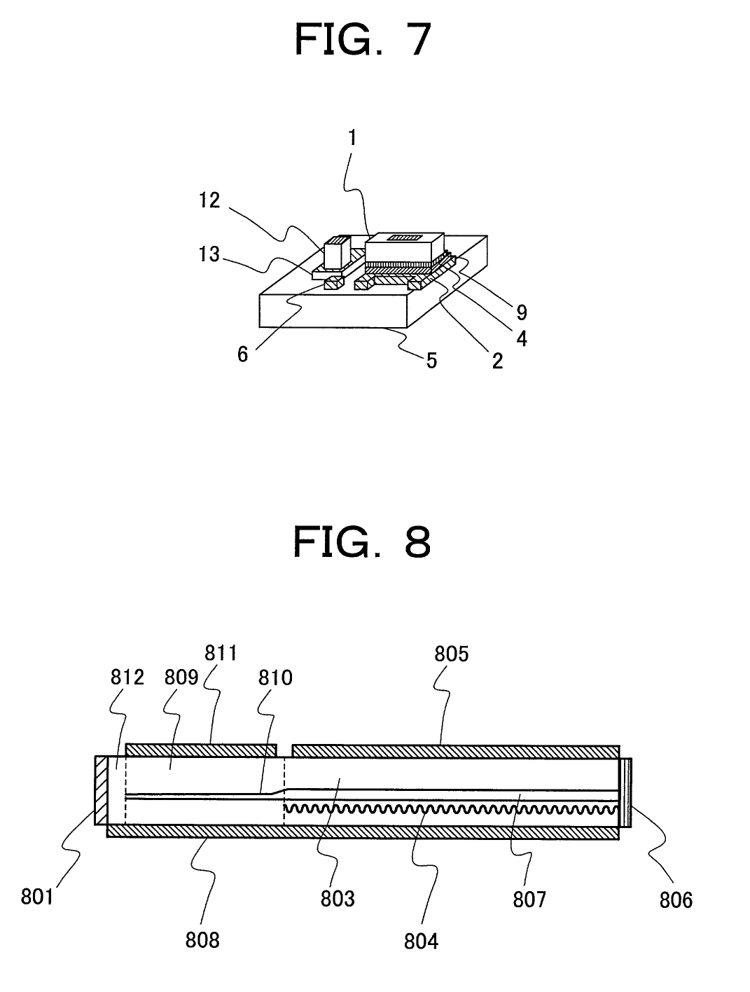

In an optical regenerated record device according to the present embodiment, well-known technique can be applied to the regenerated and recorded portion, and a semiconductor laser module according to the present invention shown in FIG. 7 is used for the light source unit 25. In FIG. 7, a reference numeral 1 denotes a GaN semiconductor laser having oscillation wavelength of 410 nm; 2, a heater; 4, insulating thin film; 9, metallic thin film; 6, a temperature sensor; 12, a photo detector; and 13, insulating thin film. The heater 2, the temperature sensor 6, the semiconductor laser 1, and the photo detector 12 are connected to the control circuit 27. The temperature control module is also incorporated in the control circuit 27, and the heater is set such that it is heated so as to become 69° C.±1° C. near the maximum temperature within an environment temperature range 0 to 70° C. Conventionally, in optical output of 40 mW, kink occurred at 8° C. or under so that a normal operation was difficult, but in the present embodiment, since the semiconductor laser is kept at high temperatures, it is possible to realize a light source unit, in which no kink occurs even though the environment temperature is 10° C. or less while optical output of 40 mW is being maintained. In this respect, in the present embodiment, the semiconductor laser is provided in so-called junction-up, that is, with a surface close to the active layer as the upper surface.

In the present embodiment, the temperature control has been set such that 69° C.±1° C. is kept, but the present invention is not limited thereto, but the setting temperature is set within a range of 10 to 70° C., that is, at environment temperatures of 10° C. or less, generation of heat of the heater may be controlled so as to keep at 10° C. or more, and at environment temperature of 10° C., the heater may be set so as not to generate heat. Also, in the present embodiment, as the semiconductor laser 1, a GaN semiconductor laser of wavelength of 410 nm has been used, but the present invention is not limited thereto, and it goes without saying that a red-color semiconductor laser having wavelength of, for example, 650 nm or 780 nm band can be also used in accordance with type of the optical disk medium.

(Fourth Embodiment)

A fourth embodiment according to the present invention is replacement of the semiconductor laser of the first embodiment with a modulator integrated laser. FIG. 8 is a longitudinal sectional view showing the modulator integrated laser. In FIG. 8, reference numerals 805 and 808 denote upper electrode and lower electrode of a semiconductor laser portion of the integrated laser light source respectively. A reference numeral 806 denotes rear end surface reflection film of the semiconductor laser portion. The oscillation wavelength of the laser portion 803 is 1.55 μm. An active layer 807 has multi-quantum well structure of InGaAsP. A single oscillation mode is obtained through the use of the DFB structure of a diffraction grid 804. In the modulator integrated laser light source, the laser portion is caused to emit laser light at all times in advance to high-speed modulate the laser light through the use of a modulator 809 located in front thereof. A multi-quantum well layer 810 within the modulator has been manufactured so as to have a larger energy band gap than the multi-quantum well layer of the laser portion. When backward voltage is applied to an electrode 811 of the modulator, the laser light is absorbed by the modulator through quantum confinement Stark effect, and the laser light does not appear in the outside. When no voltage is applied to the upper electrode 811 of the modulator portion, the laser light is not absorbed by the modulator, but is outputted in the outside. A reference numeral 812 denotes a window area of InP. Since a temperature coefficient of wavelength capable of controlling an optical signal of the modulator portion is different from a temperature coefficient of oscillation wavelength of the DFB laser, the conventional modulator integrated laser has been used by controlling the temperature at a constant temperature near room temperature through the use of the Peltier cooling element, which has become an obstacle in reducing the cost. According to the present embodiment, the energy band gap is adjusted in such a manner that the oscillation wavelengths of the semiconductor layer of the modulator portion of the modulator integrated laser of FIG. 8 and the DFB laser are activated at 85° C., and is mounted as in the case of the semiconductor laser of the first embodiment to be controlled at 85° C., whereby a transmitter for optical communication of the modulator laser can be realized at low cost. This modulator integrated laser is capable of realizing high-frequency response characteristic of 13 GHz as in the case of the conventional modulator integrated laser, which is actuated at room temperature, and of realizing a maximum transmission distance 200 km on condition that transmission is performed at transmission speed of 2.5 Gb per second through the use of normal dispersion fiber by means of low charping.

(Fifth Embodiment)

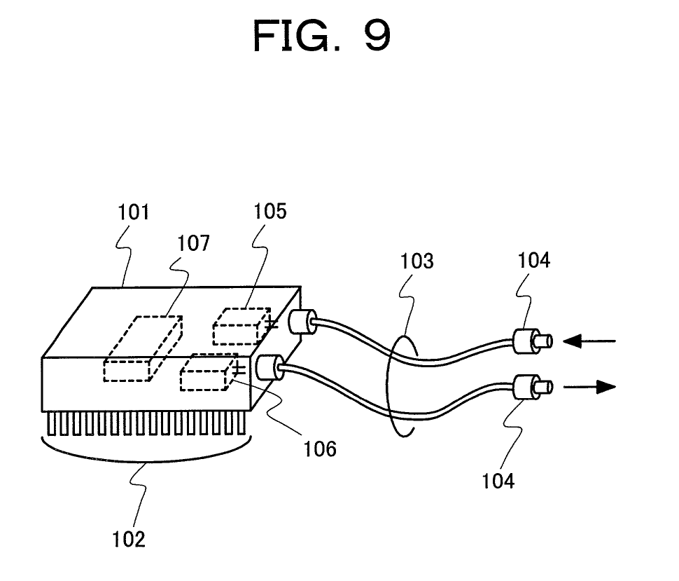

FIG. 9 shows an embodiment of an optical transmitter/receiver (transceiver) using a semiconductor laser module according to the present invention. An optical transceiver according to the present embodiment is constructed of an optical transceiver housing 101, an electric input/output pin 102, optical fiber 103, an optical connector 104, an optical receiving module 105, an optical transmitting module 106 and a signal processing/control unit 107, has a function for converting an optical signal received into an electric signal to output to the outside through the electric input/output pin 102, and a function for converting an electric signal inputted from the outside through the electric input/output pin 102 into an optical signal to transmit it. The optical fiber 103 has one end connected to the optical transceiver housing 101, and the other end connected to the optical connector 104. The optical connector 104 has structure in which received light received from an external optical transmission path (not shown) can be transmitted to the optical fiber 103, and has structure in which transmitted light received from the optical fiber 103 can be transmitted to the external optical transmission path.

The optical transceiver housing 101 houses the optical receiving module 105, the optical transmitting module 106, and the signal processing/control unit 107. For the optical transmitting module 106, a semiconductor laser module according to the present invention is used, and is constructed so as to keep the semiconductor laser at the same temperature as ambient air temperature or higher than it as in the case of the first embodiment. In this case, the ambient air temperature means to be usually temperature outside the optical transceiver housing 101, but the present invention is not limited thereto. Since the optical receiving module 105 and the optical transmitting module 106 are housed within the same housing as shown in FIG. 9, the optical receiving module 105 is to be kept at substantially the same temperature as the optical transmitting module 106, and the receiving sensitivity of the optical receiving module 105 can be kept with stability.

The signal processing/control unit 107 processes an electric signal from the optical receiving module 105 to output to the outside through the electric input/output pin 102, and processes an electric signal inputted through the electric input/output pin 102 from the outside to output to the optical transmitting module 106. In this case, the signal processing/control unit 107 may be constructed so as to have a function for controlling each element provided within the optical transceiver housing 101.

In the present embodiment, the structure has been arranged such that for the optical receiving module 105, a semiconductor laser receiving module without any temperature control function is used, and the transmitting module having the temperature control function is kept to be constant in temperature, whereby the temperature of the receiving module within the same housing is also kept to be substantially constant, but the present invention is not limited thereto, and the structure may be arranged such that the same temperature control as for the semiconductor laser of the first embodiment is applied to the semiconductor photo detector within the optical receiving module 105. In this case, the temperature of the semiconductor photo detector is kept at the same temperature as ambient air temperature or higher than it through the use of the heating element. In this case, any Peltier cooling element or the like is not used for the temperature control. The ambient air temperature usually means to be temperature outside the optical transceiver housing 101, but the present invention is not limited thereto. This causes the receiving sensitivity of the optical receiving module 105 to be kept with stability.

Even in an optical receiver having an optical receiving module 105 and no optical transmitting module 106, it goes without saying that the receiving sensitivity can be kept with stability by keeping the temperature of the semiconductor photo detector at the same temperature as ambient air temperature or higher than it through the use of the heating element. In this case, the Peltier cooling element or the like is not used for the temperature control. The ambient air temperature usually means to be temperature outside the package of the optical receiver, but it is not limited thereto. Within the package of the optical receiver, there is usually provided a signal processing unit for processing an electric signal from the semiconductor photo detector, but the present invention is not limited thereto.

According to the present invention, there is the effect that a semiconductor laser module having stable wavelength capable of being used as a light source for long-distance optical transmission can be realized at low cost and at lower power consumption. Also, there is the effect that such a semiconductor laser module can be miniaturized. Further, in the transmitting module, in which a FP laser, which is a transmitting light source for optical communication, is used, there is the effect that a transmitting module having longer transmission distance than before can be provided at low cost and at small size. Further, in the transmitting module, in which a DFB laser, which is a transmitting light source for optical communication, is used, there is the effect that a transmitting module having excellent transmission characteristic can be provided at low cost and at small size. Further, in a semiconductor laser module for optical information, there is the effect that a low-cost, small-sized, high-output optical recording module, in which a long-distance radiation image of single peak is obtainable, can be provided. Further, there is the effect that there can be realized a transceiver comprising a semiconductor laser light source and a semiconductor optical receiver which have realized wavelength stabilization at small size, at low cost, and at low power consumption. Further, another object of the present invention has the effect of being able to realize a semiconductor optical receiver which has stabilized light receiving sensitivity at small size, at low cost and at low power consumption. In addition, according to the present invention, there is the effect that it is possible to extend the transmission distance and to speed up in the use of optical communication. Also, in the use of the optical information processing apparatus, there is the effect that kink of the semiconductor laser can be reduced.

What is claimed is:

1. A semiconductor laser module comprising:
a semiconductor laser; and
control means for controlling wavelength of the light wave radiated from the semiconductor laser, wherein
said wavelength is controlled by a heating element involving no Peltier cooling.

2. A semiconductor laser module according to claim 1, wherein said semiconductor laser module has no Peltier cooling means.

3. A semiconductor laser module according to claim 2, wherein said heating element generates heat depending upon size of a driving signal from a temperature control unit.

4. A semiconductor laser module, comprising a semiconductor laser; a driving circuit for driving said semiconductor laser; a heating element for controlling temperature of said semiconductor laser; a temperature sensor for sensing temperature near or around said semiconductor laser and said heating element; and a temperature control unit for controlling said heating element on the basis of temperature information from said temperature sensor, wherein
said temperature control unit controls said heating element without the use of Peltier cooling means so as to keep said semiconductor laser at the same temperature as ambient air temperature or higher than it.

5. A semiconductor laser module according to claim 4, wherein said ambient air temperature is temperature outside a package of said semiconductor laser module.

6. A semiconductor laser module according to claim 5, wherein said semiconductor laser module has no Peltier cooling means.

7. A semiconductor laser module according to claim 6, wherein said heating element generates heat depending upon size of a driving signal from said temperature control unit.

8. A semiconductor laser module, comprising: a semiconductor laser; a driving circuit for driving said semiconductor laser; a heating element for controlling the temperature of said semiconductor laser without involving a Peltier cooling operation; a temperature sensor for sensing temperature near or around said semiconductor laser and said heating element; and a temperature control unit for controlling said heating element on the basis of temperature information from said temperature sensor, wherein
said temperature control unit controls said heating element so as to keep said semiconductor laser at the same temperature as ambient air temperature or higher than it.

9. A semiconductor laser module according to claim 8, wherein said ambient air temperature is temperature outside a package of said semiconductor laser module.

10. A semiconductor laser module according to claim 9, wherein said semiconductor laser module has no Peltier cooling means.

11. A semiconductor laser module according to claim 9, wherein said heating element generates heat depending upon size of a driving signal from said temperature control unit.

12. A semiconductor laser module according to claim 4, wherein said semiconductor laser module further comprises a supporting substrate, at least said semiconductor laser, wherein said heating element and said temperature sensor are mounted on top of said supporting substrate, and wherein said heating element controls temperature of said supporting substrate together with said semiconductor laser and said temperature sensor.

13. A semiconductor laser module according to claim 12, wherein said semiconductor laser is a Fabry-Perot type laser.

14. A semiconductor laser module according to claim 12, wherein said semiconductor laser is a distribution return shape laser.

15. A semiconductor laser module according to claim 12, wherein said semiconductor laser is a distribution return shape laser formed on the same substrate together with a field absorption modulator.

16. A semiconductor laser module according to claim 12, wherein said semiconductor laser is not cooled by Peltier cooling, but is heated by said heating element and is kept at substantially constant temperature within a predetermined temperature range, and a wavelength of light is kept substantially constant within a predetermined wavelength range to be emitted from said semiconductor laser.

17. A semiconductor laser module, comprising: a semiconductor laser; a driving circuit for driving said semiconductor laser; a heating element for controlling temperature of said semiconductor laser; a temperature sensor for sensing temperature near or around said semiconductor laser and said heating element; a temperature control unit for controlling said heating element on the basis of temperature information from said temperature sensor; and a supporting substrate, wherein
at least said semiconductor laser, said heating element and said temperature sensor are mounted on a main surface of said supporting substrate, wherein
a main surface of a semiconductor chip of said semiconductor laser, on which joining for emitting laser light has been formed, is disposed on said main surface of said supporting substrate, wherein
said heating element is disposed in proximity to said joining on said main surface of said semiconductor chip of said semiconductor laser on said main surface of said supporting substrate, and wherein
said temperature control unit controls said heating element so as to keep said semiconductor laser at the same temperature as ambient air temperature or higher than it.

18. A semiconductor laser module according to claim 17, wherein said ambient air temperature is temperature outside a package of said semiconductor laser module.

19. A semiconductor laser module according to claim 18, wherein said semiconductor laser module has no Peltier cooling means.

20. A semiconductor laser module according to claim 19, wherein said heating element generates heat depending upon size of a driving signal from said temperature control unit.

21. A semiconductor laser module according to claim 17, wherein said heating element is disposed between said main surface of said semiconductor chip of said semiconductor laser and said main surface of said supporting substrate.

22. A semiconductor laser module according to claim 21, wherein said ambient air temperature is temperature outside the package of said semiconductor laser module.

23. A semiconductor laser module according to claim 22, wherein said semiconductor laser module has no Peltier cooling means.

24. A semiconductor laser module according to claim 23, wherein said heating element generates heat depending upon size of a driving signal from said temperature control unit.

25. An optical transceiver comprising an optical receiving module and an optical transmitting module, wherein said optical transmitting module comprises: a semiconductor laser; a driving circuit for driving said semiconductor laser; a heating element for controlling temperature of said semiconductor laser without involving any Peltier cooling operation; a temperature sensor for sensing temperature near or around said semiconductor laser and said heating element; and a temperature control unit for controlling said heating element on the basis of temperature information from said temperature sensor, wherein said temperature control unit controls said heating element so as to keep said semiconductor laser at the same temperature as ambient air temperature or higher than it, and wherein
said optical transmitting module and said optical receiving module are housed within one housing.

26. An optical transceiver according to claim 25, wherein said ambient air temperature is temperature outside said housing.

27. An optical transceiver according to claim 25, wherein said optical transceiver has no Peltier cooling means.

28. An optical transceiver according to claim 27, wherein said heating element generates heat depending upon size of a driving signal from said temperature control unit.

29. An optical receiver, comprising: a semiconductor photo detector for receiving an optical information signal from a recording medium or a communication system; a signal processing unit for processing an electric signal from said semiconductor photo detector; a heating element for controlling temperature of said semiconductor photo detector; a temperature sensor for sensing temperature near or around said semiconductor photo detector and said heating element; a temperature control unit for controlling said heating element on the basis of the temperature information from said temperature sensor, wherein
said temperature control unit controls said heating element without the use of the Peltier cooling means so as to keep said semiconductor photo detector at the same temperature as ambient air temperature or higher than it.

30. An optical receiver according to claim 29, wherein said ambient air temperature is temperature outside the package of said optical receiver.

31. An optical receiver according to claim 30, wherein said optical receiver has no Peltier cooling means.

32. An optical receiver according to claim 31, wherein said heating element generates heat depending upon size of a driving signal from said temperature control unit.
